(19) United States
(12) Patent Application Publication
(10) Pub. No.: US 2013/0147009 A1
(43) Pub. Date: Jun. 13, 2013

(54) SEMICONDUCTOR DEVICE AND METHOD FOR MANUFACTURING THE SAME

(71) Applicant: Sk hynix Inc., Icheon (KR)

(72) Inventor: Dong Hoon KIM, Cheongju (KR)

(73) Assignee: Sk hynix Inc., Icheon (KR)

(21) Appl. No.: 13/673,942

(22) Filed: Nov. 9, 2012

(30) Foreign Application Priority Data
Dec. 8, 2011 (KR) 10-2011-0130829

(51) Int. Cl. H01L 23/525; H01L 21/768

(52) U.S. Cl. CPC H01L 23/5256; H01L 21/76886
USPC 257/529; 438/601; 257/E23.149; 257/E21.592

(57) ABSTRACT

A semiconductor device includes: a fuse pattern formed at a first level, a first line pattern formed at a second level lower than the first level, a second line pattern formed at a third level higher than the first level, a first contact plug coupling the fuse pattern to the first line pattern 310, a second contact plug coupling the fuse pattern to the second line pattern, and a fuse blowing region provided over first line pattern and overlapping with the first contact plug at least partially.

### CROSS-REFERENCE TO RELATED APPLICATION

The priority of Korean patent application No. 10-2011-0130829 filed on 8 Dec. 2011, the disclosure of which is hereby incorporated in its entirety by reference, is claimed.

### BACKGROUND OF THE INVENTION

Embodiments of the present invention relate to a semiconductor device and a method for manufacturing the same, and more particularly, to a semiconductor device including a fuse and a method of manufacturing the same.

In recent times, as information media such as computers have rapidly come into widespread use, technology of a semiconductor device has been rapidly developed. Functionally, it is necessary for a semiconductor device to operate at a high speed and to have a high storage capacity. Therefore, technology for manufacturing semiconductor devices has rapidly developed to improve integration degree, reliability, response speed, etc.

A process for manufacturing semiconductor devices includes a fabrication (FAB) process that forms cells each having integrated circuits by repeatedly forming predetermined circuit patterns on a silicon substrate, and an assembly process that packages the cells in chip units. An Electrical Die Sorting (EDS) process for testing electrical characteristics of cells formed over the substrate is performed between the FAB process and the assembly process.

The above-mentioned EDS process determines whether the cells formed over the substrate are in an electrically good condition or defective. The EDS process is removes defective cells before the assembly process. As a result, defective cells may be detected by the EDS process in early stages of manufacture and repaired.

Repair processes are performed as follows.

In order to increase a production yield of the semiconductor device in which a defect has occurred in the fabrication process, a redundant cell is added to substitute for the defective device or circuit. A fuse for coupling the redundant cell to the integrated circuit is also added in the manufacturing process of the semiconductor device. The repair process couples the defective cell to the redundant cell contained in the chip using the fuse for cell recovery. That is, the repair process cuts only specific fuses so that position information of cells to be repaired can be generated.

A method for repairing a semiconductor device according to the related art will hereinafter be described in detail.

First of all, after a planarized interlayer insulation film is deposited over a fuse region of the semiconductor substrate, a plurality of fuse patterns is formed over the interlayer insulation film. Thereafter, an insulation film covering the fuse patterns is deposited over the resultant semiconductor substrate. Subsequently, the insulation film over the fuse patterns is etched to have a predetermined thickness, thereby forming a fuse box pattern (or a repair-trench).

Thereafter, testing and repairing processes, e.g., using a fuse blowing process, are sequentially performed. The fuse blowing process cuts a specific fuse by applying a laser to the fuse region of the semiconductor substrate.

In this case, after the repair-trench is formed, the fuse blowing process is performed. When the insulation film remaining on the fuse pattern is thick, thermal energy can concentrate on the fuse during the fuse blowing using an e-beam and can easily reach a threshold level. As a result, an explosion occurs and the fuse is blown.

However, when the insulation film is thick, a crack occurs in a lower part of the insulation film prior to execution of the explosion, and a metal permeates into the crack, causing an unwanted short circuit. In contrast, when the insulation film remaining over the fuse pattern is thin, thermal energy tends to scatter into the air rather than concentrating on the fuse. Thus, it becomes difficult to properly blow out the fuse.

In order to properly blow the fuse, a bare metal fuse has been introduced so that the thickness of the remaining insulation film need not be adjusted. However, the bare metal fuse leaves metal residue after the bare metal fuse is blown by the laser, thus generating a defective fuse. In addition, since an upper part and sidewalls of the bare metal fuse are exposed, oxygen or moisture permeates the exposed fuse in a subsequent process (i.e., a wafer packaging process). As a result, fuse volume expansion and fuse oxidation occurs, degrading the reliability of the semiconductor device.

FIG. 1 shows a semiconductor device that includes a fuse to be blown and that is manufactured by a method according to the related art. FIG. 2 is a cross-sectional view illustrating a conventional the semiconductor device, taken along the line A-A′ of FIG. 1.

Referring to FIGS. 1 and 2, the conventional semiconductor device includes a semiconductor substrate 100, a first line pattern 110, a first contact plug 130, a fuse pattern 140, and a second line pattern 160.

The first line pattern 110 is formed over the semiconductor substrate 100, and the first contact plug 130 is formed to be coupled to one end of the first line pattern 110. The fuse pattern 140 is formed to be coupled to one end of the first contact plug 130. The fuse pattern 140 is cut as shown in the “A” region of FIG. 1.

Referring to FIG. 2, a first line layer (not shown) is formed over the semiconductor substrate 100.

A photoresist film (not shown) is formed over the first line layer, and a photoresist pattern (not shown) is formed by an exposure and development process using a first line pattern mask (not shown). The first line layer is etched using the photoresist pattern as a mask so that the first line pattern 110 is formed.

A first insulation film 120 is formed over the entire surface including the first line pattern 110.

After the photoresist film is formed over the first insulation film 120, a photoresist pattern (not shown) is formed by an exposure and development process using a contact mask. The first insulation film 120 is etched until the first line pattern 110 is exposed using the photoresist pattern as a mask, so that a contact hole (not shown) is formed. Thereafter, a conductive material is buried in the contact hole so that the first contact plug 130 is formed. In this case, the first contact plug 130 is coupled to one end of the first line pattern 110.

Subsequently, the fuse pattern 140 is formed over the first contact plug 130. Here, according to a method for forming the fuse pattern 140, after a fuse line layer (not shown) is formed, a photoresist film is formed over the fuse line layer, and a photoresist pattern is formed by an exposure and development process using a mask for fuse formation. The fuse line layer is etched until the first insulation film 120 is exposed using the photoresist pattern as a mask, so that the fuse pattern 140 is formed.

Then, a second insulation film 150 is formed over the fuse pattern 140 and the first insulation film 120.

The second line pattern 160 is formed over the second insulation film 150.

Thereafter, a third insulation film 170 is formed over the second line pattern 160 and the second insulation film 150. The center part of the fuse pattern 140 is cut as shown in the “A” region of FIG. 2.

In forming the opening shown in the “A” region, a margin with respect to a fuse pattern and a line, a size of a contact plug, and a layout space for other constituent elements need to be considered. The fuse is formed to have a large size so as to guarantee chip reliability. Due to the large fuse size, the total net die number is reduced and production costs unavoidably increase.

### BRIEF SUMMARY OF THE INVENTION

Various embodiments of the present invention are directed to providing a semiconductor device and a method for manufacturing the same that substantially obviate one or more problems due to limitations and disadvantages of the related art.

An embodiment of the present invention relates to a semiconductor device and a method for manufacturing the same, in which a first end of a fuse line is coupled to a lower end, a second end located opposite to the first end of the fuse line is coupled to an upper line, and a fuse blowing region is formed at one end of the fuse line, so that a variation of a repair condition is minimized, the fuse size is minimized, and the chip size is reduced in response to reduction of the fuse size and a net die is increased in response to reduction of the fuse size, resulting in reduction of production costs of a semiconductor product.

In accordance with an aspect of the present invention, a semiconductor device includes a first contact plug formed below a first end of a fuse pattern, and coupled to a first line; a second contact plug formed over a second end located opposite to the first end; a second line coupled to an upper part of the second contact plug, and configured to interconnect neighbor fuse patterns; and a blowing reservation region formed to expose an upper part of the first end of the fuse pattern.

The fuse pattern may include copper (Cu).

The fuse pattern may be coupled to the first contact plug, and one end parts of the neighbor fuse patterns formed over the first contact plug may be simultaneously blown.

The blowing reservation region may be formed in a square or circular shape, and may have a larger width than the first contact plug.

In accordance with another aspect of the present invention, a method for manufacturing a semiconductor device includes forming a first line over a semiconductor substrate; forming a first contact plug coupled to the first line; forming a fuse pattern coupled to an upper part of the first contact plug, wherein the first contact plug is coupled to a first end of the fuse pattern; forming a second contact plug coupled to a second end located opposite to the first end of the fuse pattern; forming a second line coupled to the second contact plug, wherein the second line is configured to interconnect neighbor fuse patterns using a plurality of second contact plugs; and forming a blowing reservation region configured to expose the first end of the fuse pattern.

The fuse pattern may include copper (Cu).

The blowing reservation region may be formed in a square or circular shape, and may have a larger width than the first contact plug.

One end parts of the neighbor fuse patterns formed over the first contact plug may be simultaneously blown.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a plan view of a semiconductor device having a fuse to be blown according to the related art.

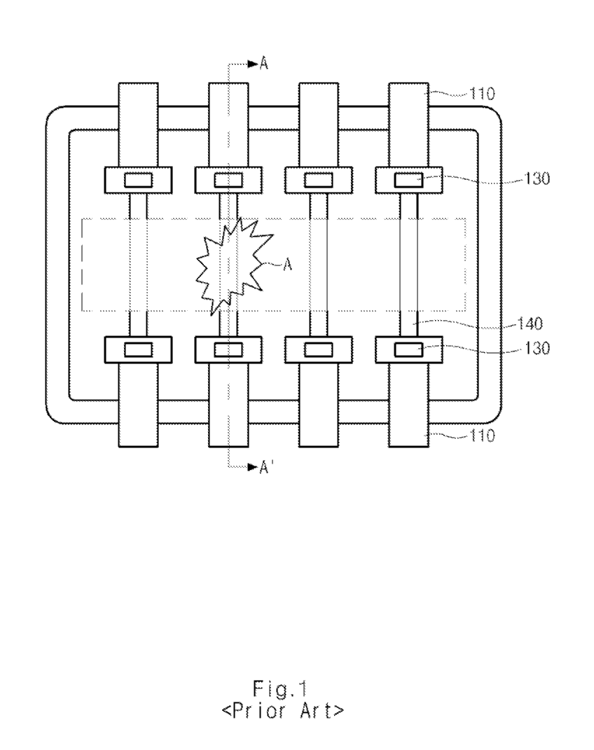

FIG. 2 is a cross-sectional view illustrating the semiconductor device taken along the line A-A′ of FIG. 1.

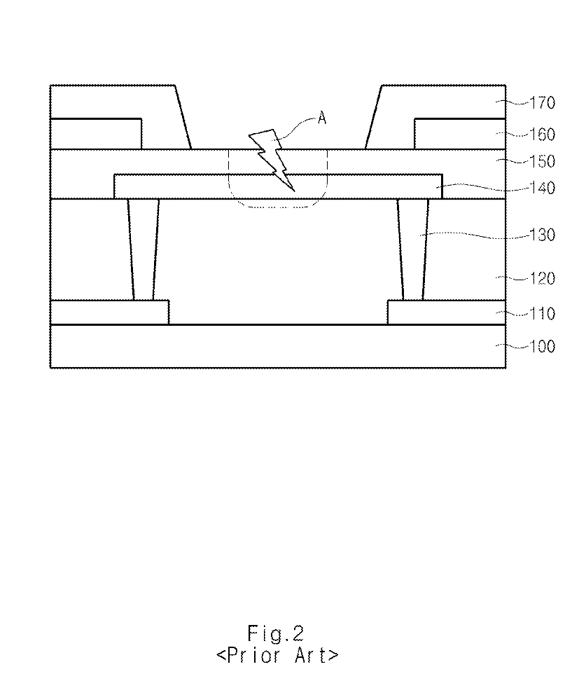

FIG. 3 is a plan view illustrating a semiconductor device manufactured by a method according to an embodiment of the present invention.

FIG. 4 is a cross-sectional view illustrating the semiconductor device of FIG. 3, taken along the line B-B′.

FIG. 5 is a block diagram illustrating a cell array according to an embodiment of the present invention.

FIG. 6 is a block diagram illustrating a semiconductor device according to an embodiment of the present invention.

FIG. 7 is a block diagram illustrating a semiconductor module according to an embodiment of the present invention.

FIG. 8 is a block diagram illustrating a semiconductor system according to an embodiment of the present invention.

FIG. 9 is a block diagram illustrating an electronic unit and an electronic system according to embodiments of the present invention.

### DESCRIPTION OF EMBODIMENTS

Reference will now be made in detail to embodiments of the present invention, examples of which are illustrated in the accompanying drawings. Wherever possible, the same reference numbers will be used throughout the drawings to refer to the same or like parts.

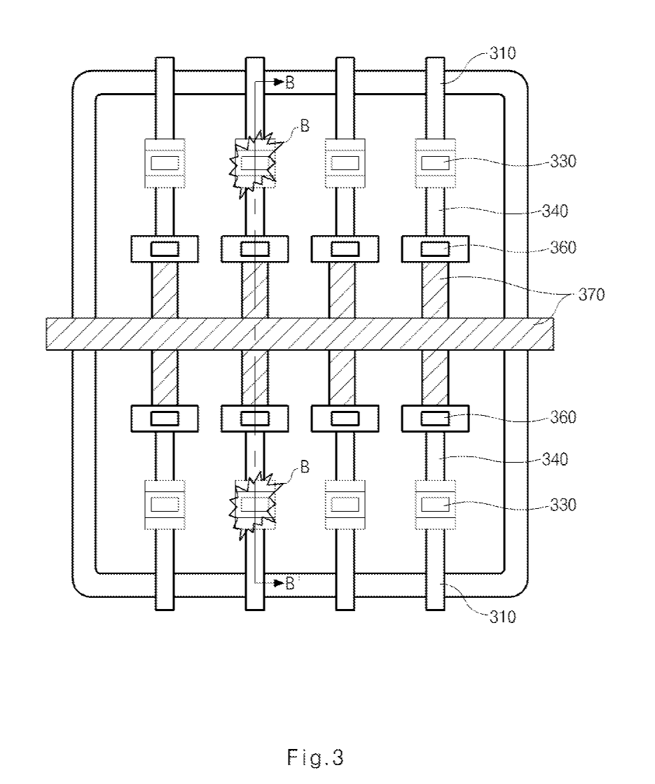

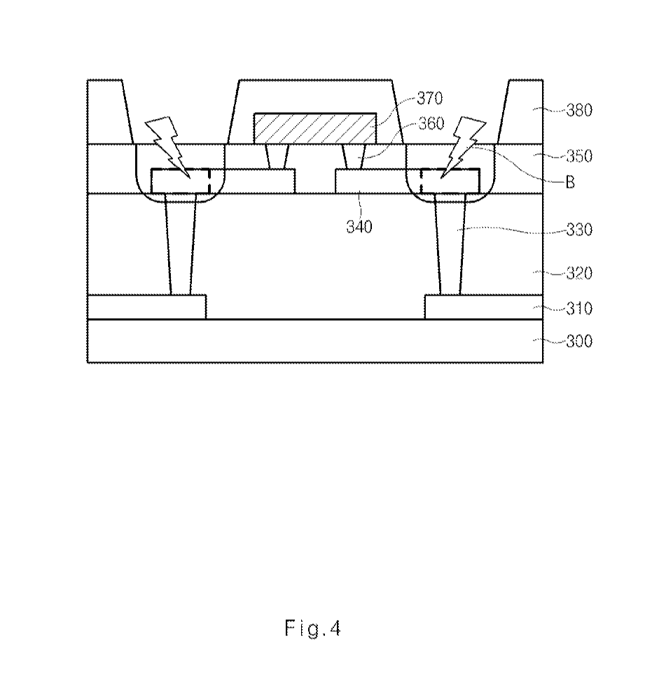

FIG. 3 is a plan view illustrating a semiconductor device manufactured by a method according to an embodiment of the present invention. FIG. 4 is a cross-sectional view of the semiconductor device taken along the line B-B′ of FIG. 3.

Referring to FIGS. 3 and 4, the semiconductor device includes a semiconductor substrate 300, a first line pattern 310, a first contact plug 330, a fuse pattern 340, a second contact plug 330, a fuse pattern 340, a second contact plug 360, and a second line pattern 370.

According to an embodiment of the present invention, the first line pattern 310 is formed over the semiconductor substrate 300, and the first contact plug 330 is coupled to one end of the first line pattern 310. Each first contact plug 330 is coupled to each first line pattern 310, and the fuse pattern 340 is coupled to one end of each first contact plug 330. The second contact plug 360 is coupled to one end of the fuse pattern 340. As a result, the second contact plug 360 is coupled to the first line pattern 310 via the first and the second contact plugs 330, 360 and the fuse pattern 340. The fuse pattern 340 may be cut at the “B” regions shown in FIG. 3.

Referring to FIG. 4, a first line layer (not shown) is formed over the semiconductor substrate 300.

A photoresist film is formed over the first line layer, and a photoresist pattern (not shown) is formed by an exposure and development process using a first line pattern mask. The first line layer is etched using the photoresist pattern as a mask so that the first line pattern 310 is formed.

A first insulation film 320 is formed over the entire surface including the first line pattern 310. Preferably, the first insulation film 320 may include an oxide film.

After A photoresist film is formed over the first insulation film 320, a photoresist pattern (not shown) is formed by an exposure and development process using a first contact mask (not shown). The first insulation film 320 is etched until the first line pattern 310 is exposed using the photoresist pattern as a mask, so that a contact hole (not shown) is formed. Thereafter, a conductive material is filled in the contact hole so that the first contact plug 330 is formed. In an embodiment, the first contact plug 330 is coupled to one end of the first line pattern 310.

Subsequently, the fuse pattern 340 is formed over the first contact plug 330. Here, according to a method for forming the fuse pattern 340, after a fuse line layer (not shown) is formed, a photoresist film is formed over the fuse line layer, and a photoresist pattern is formed by an exposure and development process using a mask defining the fuse pattern 340. A portion of the fuse line layer is etched until the first insulation film 320 is exposed using the photoresist pattern as a mask, so that the fuse pattern 340 is formed.

Then, a second insulation film 350 is formed over the fuse pattern 340 and the first insulation film 320. Preferably, the second insulation film 350 may include an oxide film.

After a photoresist film (not shown) is formed over the second insulation film 350, a photoresist pattern (not shown) is formed by an exposure and development process using a second contact mask (not shown). A portion of the second insulation film 350 is etched until the fuse pattern 340 is exposed using the photoresist pattern as a mask, so that a contact hole (not shown) is formed. Thereafter, a conductive material is filled in the contact hole so that the second contact plug 360 is formed.

Subsequently, the second line pattern 370 is formed over the second contact plug 360.

A third insulation film 380 is formed over the second line pattern 370 and the second insulation film 350. Preferably, the third insulation film 380 may include an oxide film. Then, the third insulation film 380 is pattern to form a blowing region “B” directly over the first contact plug 330.

The fuse pattern 340 may be cut in the blowing region “B” as shown in FIG. 4.

As is apparent from the above description, embodiments of the present invention provide a semiconductor device in which a first end of a fuse pattern 340 is coupled to a lower first line pattern 310, a second end of the fuse pattern 340, which is located opposite to the first end of the fuse pattern 340 is coupled to an upper second line pattern line 370, and a fuse blowing region B is formed at one end of the fuse pattern. As a result of this configuration, a variation of repair conditions can be minimized, the fuse size can be reduced, chip size can be reduced, and a net die number can be increased, resulting in a reduction in production costs of a semiconductor product.

In more detail, in the conventional art, the fuse pattern 140 is formed between two lower line patterns 110 via the first contact plugs 130. In other words, the fuse pattern 140 couples the two lower line patterns 110, which are disposed at the same level horizontally. The blowing region A is arranged between the first contact plugs 130. Thus, a total width of the fuse pattern 140 is no less than a sum of (i) a size of the “two” first contact plugs 130 and (ii) a size of the blowing region A between the “two” first contact plugs 130.

In contrast, in the present invention, the fuse pattern 340 is formed between the first and the second line patterns 310, 370 which are disposed at different levels from each other. That is, the fuse pattern 340 is formed at a first level, the first line pattern 310 is disposed at a second level that is lower than the first level, and the second line pattern 370 is disposed at a third level higher that is than the first level. The fuse pattern 340 couples the first and the second line patterns 310 and 370 to each other.

The fuse pattern 340 is coupled to the first line pattern 310 through the first contact 330. The blowing region B is arranged to overlap at least partially, and preferably overlap completely, with the contact plug 330. In the embodiment shown in FIG. 4, the blowing region B is formed directly over the first contact plug 330.

Since the blowing region B overlaps the contact plug 330 at least partially, the total width of the fuse pattern 340 can be reduced by the overlapping area. Thus, the total net die number can be increased in a given condition.

The shorter the width of the fuse pattern 340 is, the less thermal energy wasted by being scattered along the fuse pattern 340 when a blowing process is performed. That is, since less thermal energy is lost when a fuse is blown, the thermal energy can be more easily concentrated. Thus, a blowing process can be easily controlled and be performed with improved efficiency and accuracy

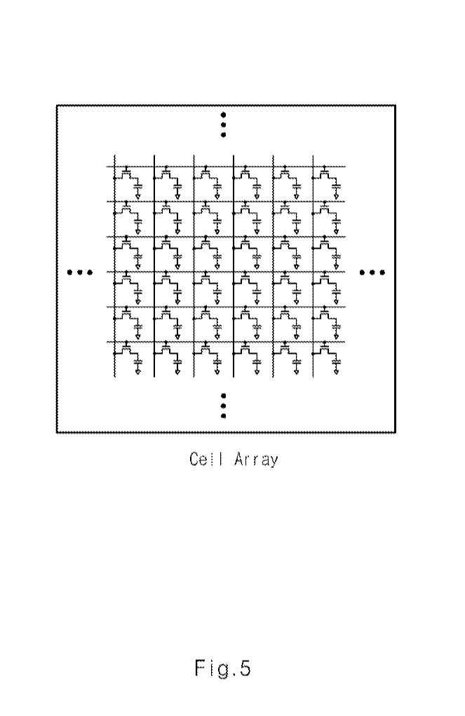

Referring to FIG. 5, the cell array includes a plurality of memory cells, and each memory cell includes one transistor and one capacitor. Such memory cells are located at intersections of bit lines BL1˜BLn and word lines WL1˜WLm. The memory cells may store or output data in response to a voltage applied to any bit line (BL1, . . . , BLn) or any word line (WL1, . . . , WLm) selected by a column decoder and a row decoder.

With respect to FIG. 5, a first direction (i.e., a bit-line direction) of the bit lines (BL1, . . . , BLn) of the cell array may be the horizontal direction, and a second direction (i.e., a word-line direction) of the word lines (WL1, . . . , WLm) may be the vertical direction, such that the bit lines (BL1, . . . , BLn) cross the word lines (WL1, . . . , WLm). A first terminal (for example, a drain terminal) of a transistor is coupled to a bit line (BL1, . . . , BLn), a second terminal (for example, a source terminal) thereof is coupled to a capacitor and a third terminal thereof (for example, a gate terminal) is coupled to the a word line (WL1, . . . , WLm). A plurality of memory cells including the bit lines (BL1, . . . , BLn) and the word lines (WL1, . . . , WLm) may be located in a semiconductor cell array.

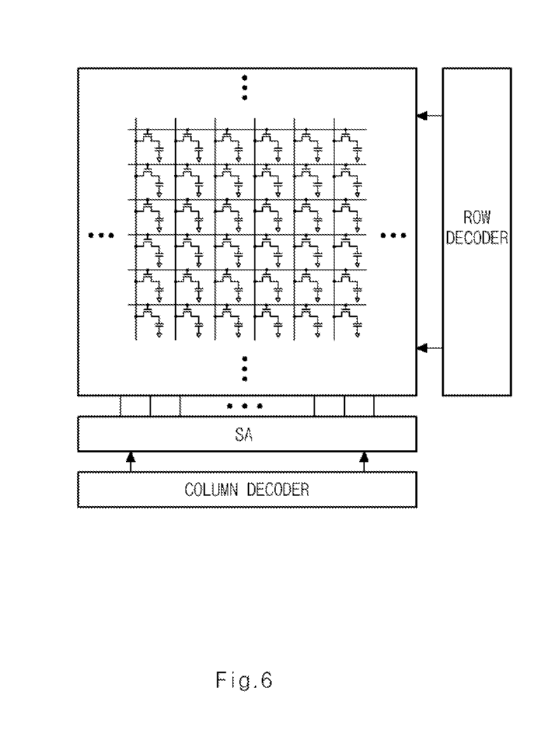

FIG. 6 is a block diagram illustrating a semiconductor device according to the present invention.

Referring to FIG. 6, a semiconductor device may include a cell array, a row decoder, a column decoder, and a sense amplifier (SA). The row decoder selects a word line corresponding to a memory cell in which a read or write operation is to be performed from among a plurality of word lines of the semiconductor cell array, and outputs a word-line selection signal (RS) to the semiconductor cell array. In addition, the column decoder selects a bit line corresponding to a memory cell in which a read or write operation is to be performed from among a plurality of bit lines of the semiconductor cell array, and outputs a bit-line selection signal (CS) to the semiconductor cell array. The sense-amplifier (SA) may sense data (BDS) stored in a memory cell selected by the row decoder and column decoder.

The semiconductor device may be coupled to a microprocessor or a memory controller. The semiconductor device may receive control signals such as WE*, RAS* and CAS* from the microprocessor, receive data through an input/output (I/O) circuit, and store the received data. The semiconductor device may be applied to a Dynamic Random Access Memory (DRAM), a P-Random Access Memory (P-RAM), an M-Random Access Memory (M-RAM), a NAND flash memory, a CMOS Image Sensor (CIS), and the like. Specifically, the semiconductor device may be applied to computers including a desktop, a laptop, or a server, and may also be applicable to a graphics memory and a mobile memory. The NAND flash memory is applicable not only to a variety of portable storage media (for example, a memory stick, a multimedia card (MMC), a secure digital (SD) card a compact flash (CF) card, an eXtreme Digital (XD) card, a universal serial bus (USB) flash drive, etc.), but also to a variety of digital applications (for example, MP3 players, PMPs, digital cameras, camcorders, memory cards, USB, game machines, navigation devices, laptops, desktop computers, mobile phones, and the like). The CMOS Image Sensor (CIS) is a charge coupled device (CCD) serving as an electronic film in digital devices, and is applicable to camera phones, Web cameras, small-sized medical imaging devices, etc.

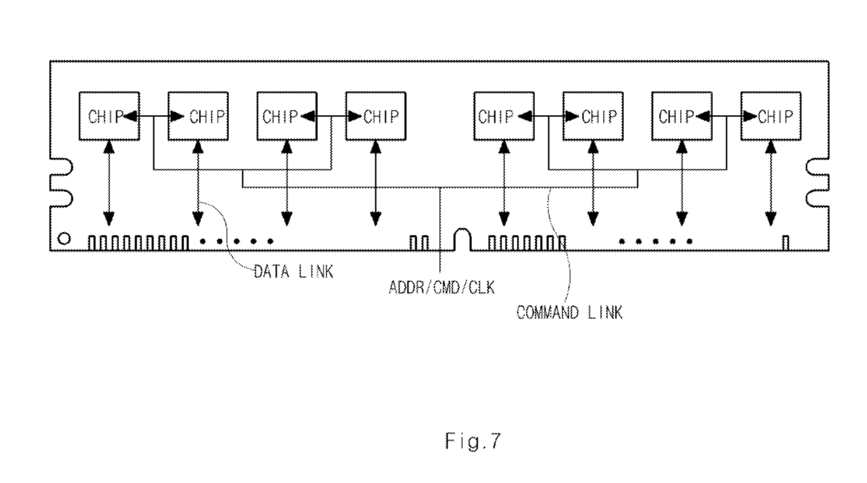

FIG. 7 is a block diagram illustrating a semiconductor module according to an embodiment.

Referring to FIG. 7, a semiconductor module includes a plurality of semiconductor devices mounted to a module substrate, a command link for enabling each semiconductor device to receive a control signal (address signal (ADDR)), a command signal (CMD), a clock signal (CLK) from an external controller (not shown), and a data link coupled to a semiconductor device so as to transmit data. The command link and the data link may be formed to be identical or similar to those of general semiconductor modules.

Although eight semiconductor chips are mounted to the front surface of the module substrate shown in FIG. 7, the semiconductor chips can also be mounted to the back surface of the module substrate. That is, the semiconductor chips can be mounted to one side or both sides of the module substrate, and the number of mounted semiconductor chips is not limited to that shown in FIG. 7. In addition, a material or structure of the module substrate is not limited to those of FIG. 6, and the module substrate may also be formed of other materials or structures.

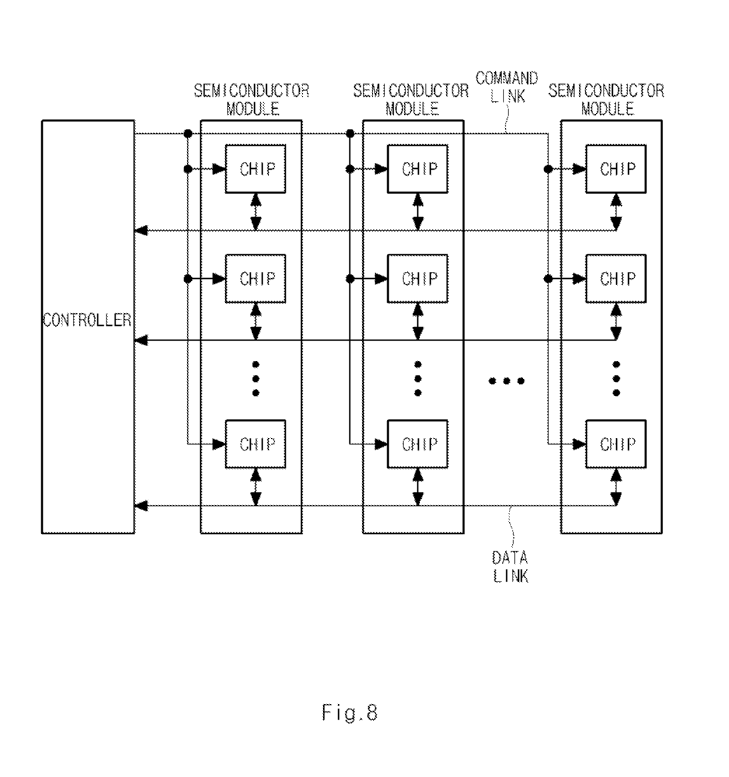

FIG. 8 is a block diagram illustrating a semiconductor system according to the present invention.

Referring to FIG. 8, a semiconductor system includes at least one semiconductor module including a plurality of semiconductor chips, and a controller for providing a bidirectional interface between each semiconductor module and an external system (not shown) so as to control the operations of the semiconductor module. The controller may be identical or similar in function to a controller for controlling a plurality of semiconductor modules for use in a general data processing system, and as such a detailed description thereof will be omitted herein. In an embodiment, the semiconductor module may be, for example, a semiconductor module shown in FIG. 7.

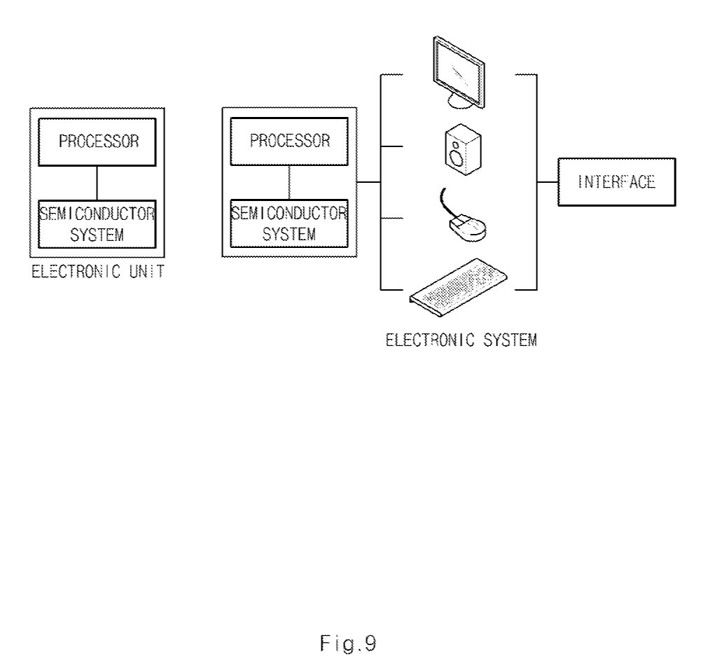

FIG. 9 is a block diagram illustrating an electronic unit and an electronic system according to an embodiment of the present invention. Referring to the drawing on the left side of FIG. 9, the electronic unit includes a semiconductor system and a processor electrically coupled to the semiconductor system. The semiconductor system of FIG. 9 may be the same as that of FIG. 9. In an embodiment, the processor may include a Central Processing Unit (CPU), a Micro Processor Unit (MPU), a Micro Controller Unit (MCU), a Graphics Processing Unit (GPU), and a Digital Signal Processor (DSP).

In an embodiment, the CPU or MPU is configured in the form of a combination of an Arithmetic Logic Unit (ALU) serving as an arithmetic and logical operation unit and a Control Unit (CU) for controlling each unit by reading and interpreting a command. If the processor is a CPU or MPU, the electronic unit may include a computer or a mobile device. In addition, the GPU is used to calculate numbers having decimal points, and corresponds to a process for generating graphical data in real-time. If the processor is a GPU, the electronic unit may include a graphic device. In addition, DSP involves converting an analog signal (e.g., voice signal) into a digital signal at a high speed, using the calculated result, re-converting the digital signal into an analog signal, and using the re-converted result. The DSP mainly calculates a digital value. If the processor is a DSP, the electronic unit may include a sound and imaging device.

In an embodiment, the processor may include an Accelerate Calculation Unit (ACU), and may be configured in the form of a CPU integrated into the GPU, such that it serves as a graphics card.

Referring to the drawing on the right side of FIG. 9, an electronic system may include one or more interfaces electrically coupled to the electronic unit. The interface may include a monitor, a keyboard, a printer, a pointing device (mouse), a USB, a switch, a card reader, a keypad, a dispenser, a phone, a display or a speaker. However, the scope of the interface is not limited thereto and is also applicable to other examples.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a first contact plug coupling a first end of a first fuse pattern to a first line pattern, wherein the first line is disposed below the fuse pattern;
a second contact plug coupled to a second end of the first fuse pattern, wherein the second end is located opposite to the first end;
a second line pattern coupled to the second contact plug, and further coupled to a second fuse pattern adjacent to the first fuse pattern; and
a blowing region formed directly over the first contact plug.

2. The semiconductor device according to claim 1, wherein the first fuse pattern includes copper (Cu).

3. The semiconductor device according to claim 1, wherein the first fuse pattern and the second fuse pattern are configured to be simultaneously blown.

4. The semiconductor device according to claim 1, wherein the blowing region is formed in a square or circular shape, and has a larger width than a width of the first contact plug.

5. A method for manufacturing a semiconductor device comprising:
forming a first line pattern over a semiconductor substrate;
forming a first contact plug coupled to the first line pattern;
forming a fuse pattern over the first line pattern, wherein the fuse pattern is coupled to the first contact plug, and wherein the first contact plug is coupled to a first end of the fuse pattern;
forming a second contact plug coupled to a second end of the fuse pattern located opposite to the first end of the fuse pattern;
forming a second line pattern over the fuse pattern, wherein the second line pattern is coupled to the second contact plug, wherein the second line pattern is further coupled to a second fuse pattern adjacent to the first fuse pattern through a third contact plug; and
forming a blowing region directly over first contact plug.

6. The method according to claim 5, wherein the first fuse pattern includes copper (Cu).

7. The method according to claim 5, wherein the blowing region is formed in a square or circular shape, and has a larger width than a width of the first contact plug.

8. The method according to claim 5, wherein the first fuse pattern and the second fuse pattern are configured to be simultaneously blown.

9. A semiconductor device comprising:
a fuse pattern formed at a first level;
a first line pattern formed at a second level lower than the first level;
a second line pattern formed at a third level higher than the first level;
a first contact plug coupling the fuse pattern to the first line pattern;
a second contact plug coupling the fuse pattern to the second line pattern; and
a fuse blowing region provided over first line pattern and overlapping with the first contact plug at least partially.

10. The semiconductor device of claim 9,
wherein the fuse blowing region is provided at the third level.

11. The semiconductor device of claim 9, the device further comprising:
a second fuse pattern coupled to the second line pattern through a third contact plug;
a third line pattern coupled to the second fuse pattern through a fourth contact plug; and
a second fuse blowing region provided over third line pattern and overlapping with the fourth contact plug at least partially.

12. The semiconductor device of claim 9,
wherein the second fuse pattern is provided at the first level, and
wherein the third line pattern is provided at the second level.
